(19) United States
(12) Patent Application Publication
(10) Pub. No.: US 2022/0200635 A1
(43) Pub. Date: Jun. 23, 2022

(54) ANALYSIS CHANNELIZERS WITH EVEN AND ODD INDEXED BIN CENTERS

(71) Applicant: Spectral DSP Corp, New York, NY (US)

(72) Inventor: Fredric J. Harris, San Diego, CA (US)

(21) Appl. No.: 17/559,840

(22) Filed: Dec. 22, 2021

Related U.S. Application Data
(60) Provisional application No. 63/129,984, filed on Dec. 23, 2020.

(51) Int. Cl. H04B 1/00; H04B 1/18; H04L 27/34; H04B 1/30

(52) U.S. Cl. CPC H04B 1/001; H04B 1/18; H04B 2001/307; H04B 1/30; H04L 27/345

(57) ABSTRACT

Analysis channelizers are provided. In one embodiment, the channelizer includes an M-path filter receiving an input signal; a circular buffer in communication with the M-path filter; and an M-point inverse fast Fourier transform (IFFT) circuit in communication with the circular buffer, such that the channelizer aligns spectra of the input signal with spectral responses an odd length, non-maximally decimated filter bank by alternating sign heterodyne of the input signal. The channelizer applies an equivalency theorem to the non-maximally decimated filter bank formed by an odd length polyphaser filter. Advantageously, the M-path filter does not require on-line signal processing to obtain odd-indexed filter centers. In another embodiment, the channelizer alternates a sign heterodyne of a filter coefficient weight.

### RELATED APPLICATIONS

This application claims priority to U.S. Provisional Patent Application Ser. No. 63/129,984 filed on Dec. 23, 2020, the entire contents of which is expressly incorporated by reference herein.

### TECHNICAL FIELD

The present disclosure relates generally to the field of signal processing. More particularly, the present disclosure relates to analysis channelizers with even and odd indexed bin centers.

### RELATED ART

In the signal processing field, channelizers are known algorithms executed by digital signal processors (DSPs) which select a certain frequency band from an input radiofrequency (RF) signal. The standard M-path analysis channelizer center frequencies coincide with the M sampled data frequencies of the M-point discrete Fourier transform (DFT), the frequencies with integer number of cycles per length of M-samples. These are the M multiples of f_{S}/M, the frequencies that alias to direct current (DC) when their sinusoids are down sampled M-to-1. The spacing between center frequencies is also f_{S}/M as is the output sample rate when maximally decimated.

There is a channelizer variation that has its center frequencies offset by the half channel spacing. These center frequencies are located midway between the DFT frequencies and contain (2M+1)/2 cycles per interval per length of M-samples. In this channelizer, the index 0 is not the center frequency of the baseband channel, but rather, the crossover frequency of the adjacent bins centered at ±0.5 cycles per interval. The filters have the same bandwidth and have the same sample rate of the DFT bin centered channelizer. Changes to the standard channelizer to obtain the offset channelizer require a complex heterodyne of the input series or a complex heterodyne of the filter coefficients.

Let us consider a DFT for an odd number of points, say 15 for example. Such a DFT can be implemented by a Good-Thomas (GT) algorithm or by a conventional mixed radix Cooley-Tukey (CT) algorithm. An advantage of using the GT transform is there are no twiddle factors in the algorithm and the arithmetic is performed with real arithmetic and requires fewer arithmetic operations. As a side note, a 16 point CT fast Fourier transform requires 36 real multiplies while a 15 point GT fast Fourier transform requires 10 real multiplies. Interesting and useful modifications to the channelizer structure can be implemented, which avoids the complex heterodyne when converting between the channelizer options. By avoiding the complex multiplies at the input sample rate, the modified channelizers have a reduced signal processing workload. Accordingly, what would be desirable are analysis channelizers which address the foregoing, and other, needs.

### SUMMARY

The present disclosure relates to analysis channelizers. In one embodiment, the channelizer includes an M-path filter receiving an input signal; a circular buffer in communication with the M-path filter; and an M-point inverse fast Fourier transform (IFFT) circuit in communication with the circular buffer, such that the channelizer aligns spectra of the input signal with spectral responses an odd length, non-maximally decimated filter bank by alternating sign heterodyne of the input signal. The channelizer applies an equivalency theorem to the non-maximally decimated filter bank formed by an odd length polyphaser filter. Advantageously, the M-path filter does not require on-line signal processing to obtain odd-indexed filter centers. In another embodiment, the channelizer alternates a sign heterodyne of a filter coefficient weight.

### BRIEF DESCRIPTION OF THE DRAWINGS

The foregoing features of the invention will be apparent from the following Detailed Description of the Invention, taken in connection with the accompanying drawings, in which:

FIG. 1 is a diagram illustrating spectra of channelizers with even and with odd indexed center frequencies with same channel shape, bandwidth, and frequency spacing, such that upper subplot centers match DFT center frequencies are centered on half the even integers and lower subplot centers are offset by half their spacing centered on half the odd integers;

FIG. 2 is a diagram illustrating alignment of spectra of an input signal with spectral responses of a filter bank by complex heterodyne of input signal in upper subplot or by complex heterodyne of filter coefficient weights in lower subplot;

FIG. 3 is a diagram illustrating two unit circles with roots of (Z¹⁵−1) and frequencies corresponding to a 15 point discrete Fourier transform (DFT), such that the left subplot indicates the location of DC or zero frequency of an unaltered input sequence presented to the DFT, and the right subplot indicates the location of DC or zero frequency heterodyned to the half sample rate by an alternating the sign heterodyne of the input sequence;

FIG. 4 is a diagram illustrating polyphase filter input sample indices and sign of input heterodyne for two successive 15-point data samples in a 15-path polyphase filter;

FIG. 5 is a diagram illustrating polyphase filter input sample indices and sign of input heterodyne for two successive 10-point data sample sequences in a 15-path polyphase filter, such that there are no sign reversals of the two new input vectors;

FIG. 6 is a diagram illustrating an analysis channelizer in accordance with the present disclosure;

FIG. 7 is a diagram illustrating spectra of input signal and channel centers of 15-path polyphase channelizer performing 10-to-1 down sampling with alignment of channelizer spectra with half-channel bandwidth offset performed by embedding alternating sign heterodyne in filter weights; the lower 15 subplots show spectra obtained at each baseband channel output port; and

FIG. 8 is a diagram illustrating two unit circles with roots of (Z¹⁸−1), wherein the frequencies correspond to an 18 point DFT; the left subplot indicates the location of DC or zero frequency of an unaltered input sequence presented to the DFT, and the right subplot indicates the location of DC or zero frequency heterodyned to the quarter sample rate by exp(j n π/2) heterodyne of the input sequence.

### DETAILED DESCRIPTION

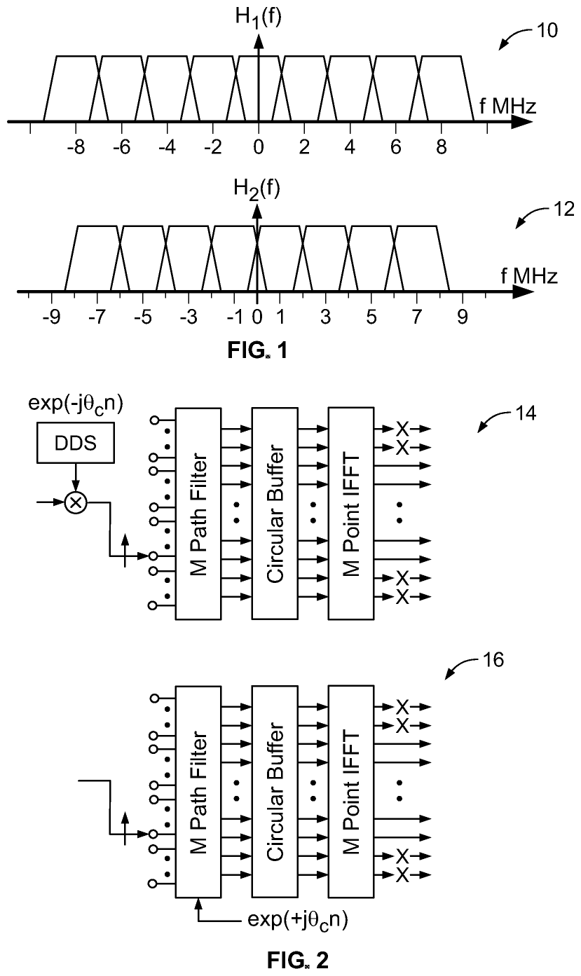

The present disclosure relates to analysis channelizers with even and odd indexed bin centers, as described in detail below in connection with FIGS. 1-8.

FIG. 1 illustrates operation of a known channelizer, whereby in the fast Fourier transform (FFT), there is the same symmetry of the spectral points about index 0 as there is about index 8 (or M/2). MATLAB's fftshift command can be used to interchange index 0 and index M/2 for display purposes. This exchange preserves the spectral symmetries of an even length FFT but it is not preserved for an odd length FFT. The spectra of two channelizers is presented with equally spaced center frequencies, say 2 MHz, but with different center frequency locations. In the upper subplot 10, the center frequencies reside on half the even integer frequencies Δf·(2k)/2 while in the lower subplot 12, the center frequency reside on half the odd integer frequencies Δf·(2k+1)/2. The filters have the same shape, bandwidth, and sample rate in their respective implementations.

The standard response to the problem that a signal and a filter do not reside at the same center frequency is to move one of them: the signal to the filter (by the Armstrong heterodyne) or the filter to the signal (using the Equivalency theorem). These two options are shown in FIG. 2, which illustrates two processing circuits 14, 16 that perform the aforementioned signal movements. In both cases, a complex heterodyne at the input rate is required to perform the spectral alignment. While the frequency shift of the input signal or of the filter frequency response solves the offset problem, it does so at some cost. Rather than shift the input signal's spectrum or the filter's spectrum half a bin width, we can consider a much larger, spectral shift, but a shift less expensive to implement. We start by examining the FFT that implements the DFT. Here we discuss the FFT even though the channelizer uses the IFFT because we more easily visualize frequency bins when we see the FFT. Many FFTs are implemented by the radix-2 Cooley-Tukey algorithm which is a transform for an even number of points, say 16 for example.

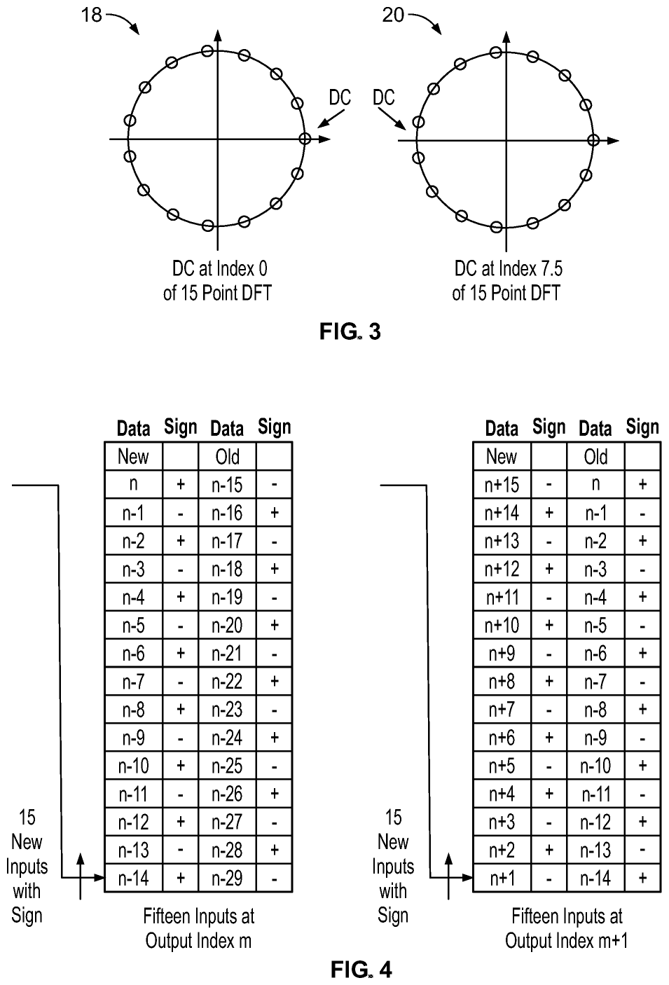

FIG. 3 is a diagram illustrating the root locations of Z¹⁵−1 which corresponds to the center frequencies of a 15 point DFT. On the left subplot 18, the zero frequency location of an unaltered input sequence is indicated on the circle. This coincides with index 0 of the 15 point DFT. On the right subplot 20, the zero frequency location of the input sequence following a heterodyne to the half sample rate by alternating signs is indicated at the half sample rate on the circle. The DC term is seen to reside midway between indices 7 and 8 of the 15 point DFT. This means that the indices 7 and 8 correspond to the two frequencies below and above DC by half the channel spacing. In this process, we do not have to a apply complex heterodyne to the input series or to the filter weights to access the half bandwidth offset frequency channelizer responses. The interaction of the odd length DFT and the alternating sign input heterodyne place the offset input frequency centers in the DFT bin centers. We simply have to relabel the bin indices to the offset center frequencies of the half sample rate rotated input spectrum. The mapping from bin index k to center frequency index fₖ is shown in equation (1), below. For this example, if f_{S}=150 MHz and M=15, frequency f₈ is shown in (2) to be +5 MHz.

$$\begin{matrix}{f}_{k} = ( k \frac{{f}_{S}}{M} - \frac{{f}_{S}}{2} ) & ( 1 ) \\ \begin{matrix}{f}_{8} = ( 8 \frac{150}{15} - \frac{150}{2} ) MHz \\ = ( 8 \times 10 - 75 ) = 5 MHz\end{matrix} & ( 2 )\end{matrix}$$

The benefits of selecting an M-path channelizer with M selected to be odd integer were explored. We used the fact that while DC resided on an FFT index, the half sample rate resided midway between a pair of FFT indices. The input heterodyne of DC to the half sample rate placed bin centers offset from DC by half the channel spacing. We still have to access alternate input samples to perform sign reversals. While we have avoided the complex rotation we are still accessing input samples at the high input sample rate. We wonder if we can use the odd length FFT with the embedded offset at the half sample rate but avoid the heterodyne of the signal to the half sample rate. We now examine how the alternating sign input data interacts with the filter coefficients.

FIG. 4 shows the input data index and the data signs for two successive inputs of 15 new input samples to 15 point polyphase filter operating in its maximally decimated form. Note the sign reversals of the corresponding sample positions in the two new input vectors. These sign reversals cause the path outputs to have the desired sign reversals of the input heterodyne. We could use a state machine with embedded sign reversals in the polyphase filter coefficients to obtain the same sign flipping behavior seen in FIG. 4, but a different option quickly presents itself

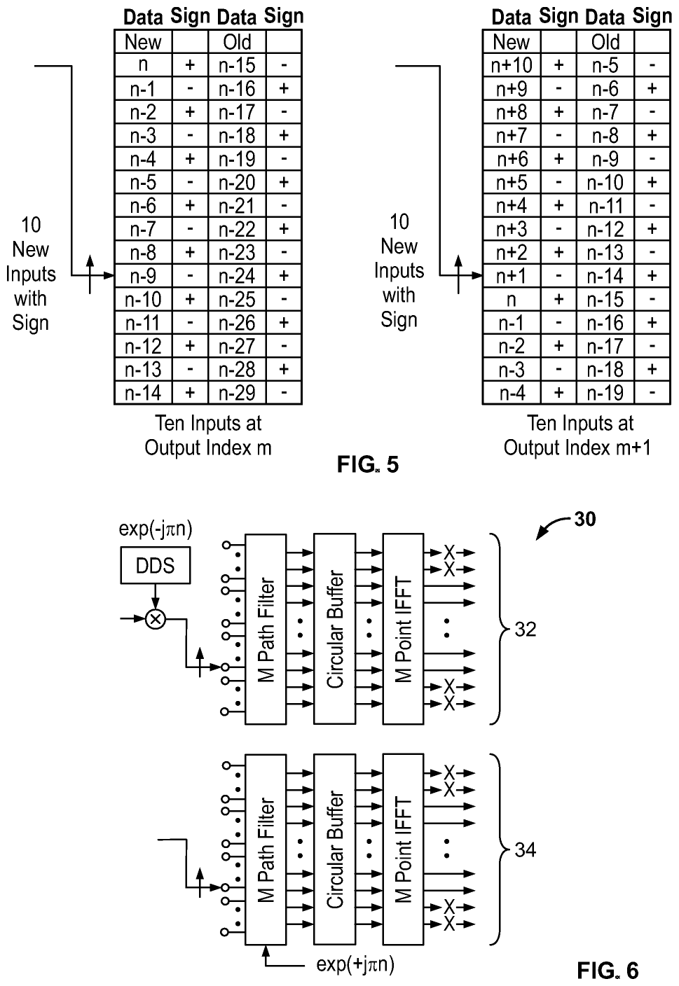

FIG. 5 shows the input data index and the alternating data signs for two successive inputs of 10 new input samples to 15 point polyphase filter operating in its non-maximally decimated 10-to-1 down sampling form. We note that there are no sign changes in corresponding positions of successive 10-sample input vectors in the non-maximally decimated version of the 15 path filter. This is because the length of the successive input vectors is 10 which is a multiple of the 2 sample period of the sign changes of the input heterodyne. Because the signs don't change on successive inputs, we can associate the signs with the filter weights. That is, rather than heterodyne the input samples to the half sample rate at the input sample rate, we heterodyne the filter weights as an off-line operation. This is an interesting version of the equivalency theorem embedded in the polyphase filter.

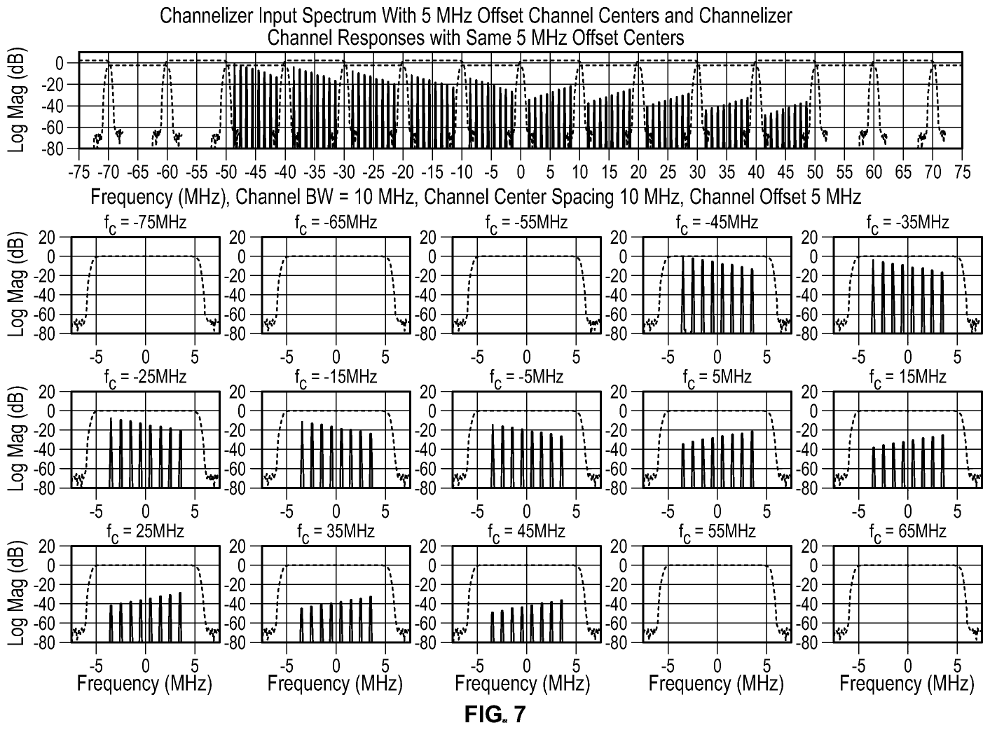

FIG. 6 is a diagram illustrating an alignment channelizer in accordance with the present disclosure, indicated generally at 30. The channelizer 30 can be implemented as a first processing circuit 32 or a second processing circuit 34, each having an M-path filter, a circular buffer, and an M-point IFFT circuit. Either, or both, of the circuits 32, 34 could also include a direct digital synthesizer (DDS) circuit. The first processing circuit 32 aligns spectra of an input signal with spectral responses of an odd length, non-maximally decimated filter bank by alternating sign heterodyne of the input signal. The second processing circuit 34 alternates the sign heterodyne of filter coefficient weights. The channelizer 30 applies the equivalency theorem to the non-maximally decimated filter bank formed by an odd length polyphase filter. Interestingly, there is no on-line signal processing required to obtain the odd-indexed filter centers in this version of the M-path filter.

It is noted that the channelizer 30 (whether implemented as the first processing circuit 32 or the second processing circuit 34) could be implemented using any suitable processor such as an application-specific integrated circuit (ASIC), a digital signal processor (DSP), a field-programmable gate array (ASIC), a microprocessor, or as software executed by a general-purpose processor. It is additionally noted that the channelizer 30 could be implemented in a radiofrequency transceiver, which could include, but is not limited to, a cellular transceiver (e.g., base station or mobile device supporting one or more communications protocols such as 3GPP, 4G, 5G, etc.), a satellite transceiver (e.g., an earth station or a satellite in space), a wireless networking transceiver (e.g., a WiFi base station or WiFi-enabled device), a short-range (e.g., Bluetooth) transceiver, or any other radiofrequency transceiver.

FIG. 7 shows the input and output spectrum formed by the 15-path polyphase filter with alternating sign heterodyne embedded in filter weights, which produces acceptable results.

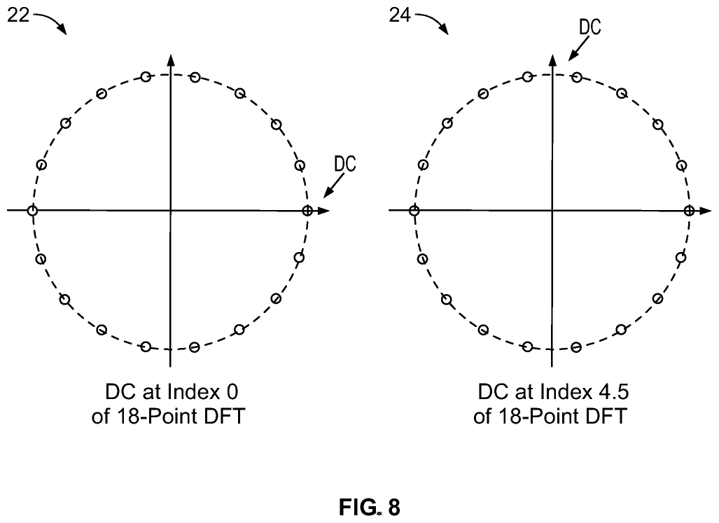

If there is a need for an even length transform, one would lose the half sample rate being located midway between DFT frequency indices. We can still use the spectral location between DFT indices at the quarter sample rate. As an example, FIG. 8 shows, at left subplot 22, DC at index 0 of an 18 point DFT without the heterodyne and, at right subplot 24, midway between indices 4 and 5 of the 18 point DFT as a result of an input heterodyne by exp(j n π/2). To be able to embed the phase shifts in the polyphase filter the down sample rate P must be a multiple of 4 to keep the phase changes stationary in the filter on successive inputs of length P. We demonstrated successful operation of this modified process with an 18-path filter and 18-point FFT performing 12-to-1 down sampling. There is, of course, a re-indexing required to locate the shifted frequency centers at the offset DFT output indices.

Disclosed herein is an M-channel analysis channelizer with frequency bin centers offset from DC by half their channel spacing. This bin location variation is traditionally referred to as odd indexed bin centers. The reason designs use the odd indexed bin centers is that one can form a symmetric allocation of channels with an even number of bin centers. When we have the even indexed bin centers, the symmetric channel assignment have an odd number of channels with one channel centered at DC which may or may not be occupied. Many OFDM based systems avoid centering a channel at DC due to the DC bin corruption by various DC intrusion sources. These sources include analog mixers self-mixing components, analog-to-digital converter (ADC) truncation quantization of input samples, and 2's complement bias due to truncation arithmetic. The traditional response to aligning the bin centers of an analysis channelizer with the offset bin centers of a multichannel odd indexed bin centered received signal is a complex heterodyne applied to the received signal. Another option embeds the heterodyne in the filter weights of the channelizer. As disclosed herein, a channelizer with an odd number of paths and an odd number center frequencies in its IFFT algorithm had an interesting symmetry anomaly. The IFFT bin centers symmetric about DC include the DC bin but the bin centers symmetric about the half sample rate bracketed the half sample rate. The half sample rate resided midway between IFFT bins, the property we desired in the odd indexed channelizer. By translating DC to the half sample rate of a channelizer with an odd number of paths, we had the odd indexed channelizer without the complex heterodyne of data or filter weights. We then showed that under simple conditions, the sign reversals of the signal samples could be embedded in the polyphase filter weights so no operation was applied to input samples at the high input sample rate.

Having thus described the system and method in detail, it is to be understood that the foregoing description is not intended to limit the spirit or scope thereof. It will be understood that the embodiments of the present disclosure described herein are merely exemplary and that a person skilled in the art can make any variations and modification without departing from the spirit and scope of the disclosure. All such variations and modifications, including those discussed above, are intended to be included within the scope of the disclosure. What is desired to be protected by Letters Patent is set forth in the following claims.

What is claimed is:

1. An analysis channelizer, comprising:
an M-path filter receiving an input signal;
a circular buffer in communication with the M-path filter; and
an M-point inverse fast Fourier transform (IFFT) circuit in communication with the circular buffer,
wherein the channelizer aligns spectra of the input signal with spectral responses an odd length, non-maximally decimated filter bank by alternating sign heterodyne of the input signal.

2. The channelizer of claim 1, wherein the channelizer applies an equivalency theorem to the non-maximally decimated filter bank formed by an odd length polyphaser filter.

3. The channelizer of claim 1, wherein the M-path filter does not require on-line signal processing to obtain odd-indexed filter centers.

4. The channelizer of claim 1, wherein the channelizer is implemented using one or more of an application-specific integrated circuit (ASIC), a digital signal processor (DSP), a field-programmable gate array (ASIC), a microprocessor, or software executed by a general-purpose processor.

5. The channelizer of claim 1, wherein the channelizer is implemented in a radiofrequency transceiver including one or more of a cellular transceiver, a satellite transceiver, a wireless networking transceiver, or a short-range transceiver.

6. An analysis channelizer, comprising:
an M-path filter receiving an input signal;
a circular buffer in communication with the M-path filter; and
an M-point inverse fast Fourier transform (IFFT) circuit in communication with the circular buffer,
wherein the channelizer alternates a sign heterodyne of a filter coefficient weight.

7. The channelizer of claim 6, wherein the channelizer applies an equivalency theorem to a non-maximally decimated filter bank formed by an odd length polyphaser filter.

8. The channelizer of claim 6, wherein the M-path filter does not require on-line signal processing to obtain odd-indexed filter centers.

9. The channelizer of claim 6, wherein the channelizer is implemented using one or more of an application-specific integrated circuit (ASIC), a digital signal processor (DSP), a field-programmable gate array (ASIC), a microprocessor, or software executed by a general-purpose processor.

10. The channelizer of claim 6, wherein the channelizer is implemented in a radiofrequency transceiver including one or more of a cellular transceiver, a satellite transceiver, a wireless networking transceiver, or a short-range transceiver.
